(19) United States
(12) Patent Application Publication
(10) Pub. No.: US 2008/0036049 A1
(43) Pub. Date: Feb. 14, 2008

(54) STACKED INTEGRATION MODULE AND METHOD FOR MANUFACTURING THE SAME

(76) Inventors: Jae-Hyuck Lee, Anyang-si (KR); Young-Min Lee, Yongin-si (KR); Shin-Hee Cho, Suwon-si (KR); Jae-Young Huh, Seoul (KR); Ji-Hyun Jung, Seoul (KR)

Correspondence Address: CHA & REITER, LLC, 210 ROUTE 4 EAST STE 103, PARAMUS, NJ, 07652, US

(21) Appl. No.: 11/696,750

(22) Filed: Apr. 5, 2007

(30) Foreign Application Priority Data
Aug. 9, 2006 (KR) 75330/2006

(51) Int. Cl. H01L 23/552; H01L 21/60

(52) U.S. Cl. 257/659; 438/122; 257/E21.506; 257/E23.114

(57) ABSTRACT

Disclosed is a stacked integration module having a small thickness while guaranteeing thermal and operational stabilities when operated at high frequencies. The stacked integration module includes a printed circuit board having first and second surfaces facing each other, at least one hole extending through the first and second surfaces, and a recess formed on the second surface; and a metallic member having an upper surface, the second surface of the printed circuit board being seated on the upper surface while making contact with the upper surface. The stacked integration module is simpler than conventional modules in terms of structure and process. The metallic member, which is made of a plate-shaped material having a larger area than conventional heat-radiation means, is advantageous for cooling and electromagnetic wave shielding.

### CLAIM OF PRIORITY

This application claims priority to an application entitled “Stacked Integration Module and Method for Manufacturing the Same,” filed with the Korean Intellectual Property Office on Aug. 9, 2006 and assigned Serial No. 2006-75330, the contents of which are hereby incorporated herein by reference.

### BACKGROUND OF THE INVENTION

1. Field of the Invention

The present invention relates to a stacked integration module, and more particularly, to a stacked integration module which is resistant to heat and radiation, and which has a slim size.

2. Description of the Related Art

Stacked integration modules, which have compact size and which can perform multiple functions, are widely used for highly-integrated portable electronic devices (e.g. portable terminals). Due to the characteristics, SIP (System In Package) type modules have prevailed in the field.

Conventional stacked integration modules include semiconductor chips and active/passive devices integrated on a PCB. When high-frequency components that radiates electromagnetic waves are integrated together with semiconductor chips that generate much heat, separate means for preventing radiation of the electromagnetic waves and the heat must be provided.

FIG. 1 is a sectional view of a conventional stacked integration module 100. The module has a PCB 110, on which a molding 120, input/output pads, and an electromagnetic wave shield 132.

As shown in FIG. 1, a semiconductor chip 133, a plurality of passive devices 134, and a high-frequency device 131 may be integrated on the upper surface of the PCB 110. These devices may be connected to the PCB directly or by wires.

In the conventional module 100 containing a semiconductor chip 133 that generates much heat and a high-frequency device 131 that generates electromagnetic waves, separate means suppressing generated heat and electromagnetic waves are needed. As such, the PCB 110 of the conventional module 100 provides a hole 111, which acts as a means for cooling the semiconductor 133, extending through the PCB 110 where the semiconductor chip 133 is seated. The hole 111 is connected to an underlying heat-radiation pad or is directly exposed to the atmosphere.

Meanwhile, a shield can 132, which acts as a means for preventing radiation of electromagnetic wave by enclosing the high frequency device 131, is seated on the PCB 110. The shield can 132 has an opening on a part of its upper surface.

The conventional stacked integration module 100 further contains a molding 120 that is adapted to protect the PCB 110 and the devices positioned thereon.

FIG. 2 is a sectional view showing another conventional stacked integration module 200. The module has a PCB 210, on which a semiconductor chip 236, a high-frequency device 231, and a number of passive devices are mounted. In addition, input/output pads are positioned beneath the PCB 210.

The semiconductor chip 233 has a heat-radiation member 236 positioned thereon so as to cool the semiconductor chip 233. The heat-radiation member 236 is generally made of a metallic material and is positioned so that a portion of the member makes direct contact with the semiconductor chip 233. Meanwhile, the shield can 231 shown in FIG. 1 may be is used for the high-frequency device 231.

The conventional integration modules, however, have several deficiencies. In particular, as the heat-radiation member and the shield can must be provided separately in the conventional integration modules, processes of manufacturing each of the heat-radiation member and the shield can must be added to the process of manufacturing the conventional integration modules. The addition of the process of manufacturing the heat-radiation member and the shield can renders the process of manufacturing the conventional integration modules less than ideal.

In addition, provision of separate heat-radiation member and the shield can increases the volume of the modules.

Further, the heating efficiency of the conventional integration module is limited by two conflicting and competing requirements. In particular, the heating efficiency depends on the size of the heat-radiation member of the integration modules, and superior heating efficiency requires the size of the heat-radiation member to be large. However, the size of the heat-radiation member is restricted by the requirement that the heat-radiation member be mounted on portable electronic devices. As the conventional integration module attempts to address both requirements, the heating efficiency of the conventional integration modules ultimately suffers and becomes limited.

### SUMMARY OF THE INVENTION

Accordingly, the present invention has been made to solve the above-mentioned problems occurring in the prior art, and provides additional advantages by providing a stacked integration module having a small thickness and having thermal and operational stabilities when operated at high frequencies.

One aspect of the present invention provides a stacked integration module including a printed circuit board having first and second surfaces facing each other, at least one hole extending through the first and second surfaces, and a recess formed on the second surface; and a metallic member having an upper surface, the second surface of the printed circuit board being seated on the upper surface while making contact with the upper surface.

Another aspect of the present invention provides a method for manufacturing a stacked integration module, the method including the steps of forming a printed circuit board having at least one hole and a recess; integrating a high-frequency device in the recess and making electrical connection; attaching a metallic member to a surface of the printed circuit board, the recess being formed on the surface; inserting a semiconductor chip into the hole so that a surface of the semiconductor chip makes contact with the metallic member; and integrating a plurality of passive devices on the printed circuit board and forming a molding on the printed circuit board.

### BRIEF DESCRIPTION OF THE DRAWINGS

The above features and advantages of the present invention will be more apparent from the following detailed description taken in conjunction with the accompanying drawings, in which:

FIG. 1 is a sectional view showing a conventional stacked integration module;

FIG. 2 is a sectional view showing another conventional stacked integration module;

FIG. 3 is a sectional view showing a stacked integration module according to one aspect of the present invention; and

FIGS. 4 to 10 show respective steps for manufacturing a stacked integration module according to the present invention.

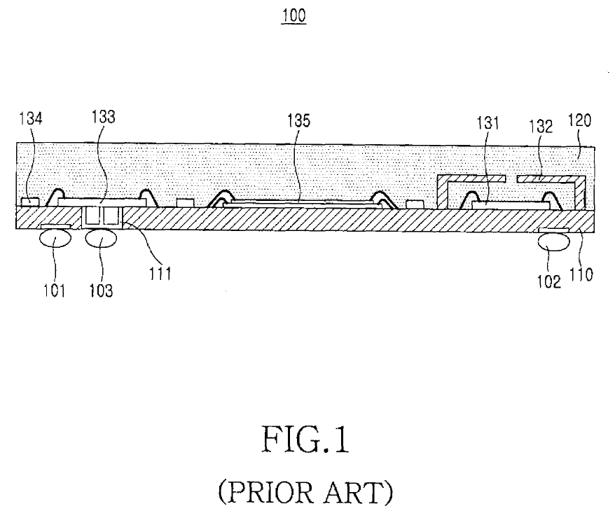

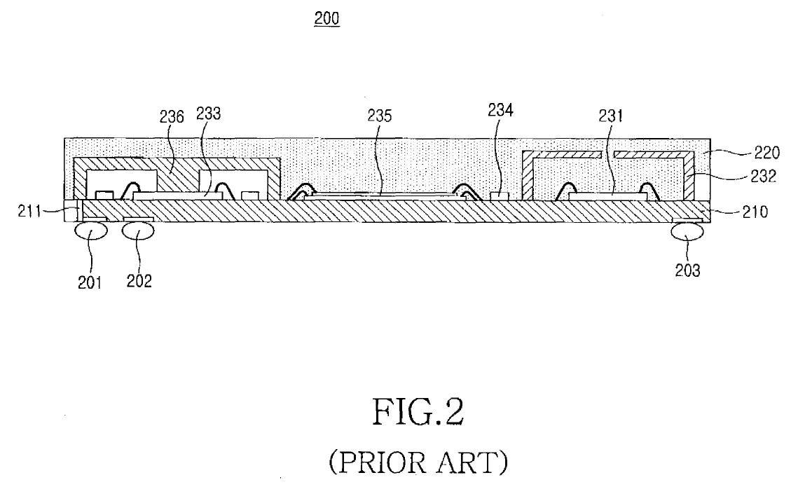

### DETAILED DESCRIPTION OF THE INVENTION

Hereinafter, several aspects of the present invention will be described with reference to the accompanying drawings. For the purpose of clarity and simplicity, detailed descriptions of known functions and configurations are omitted, as they may make the subject matter of the present invention unclear.

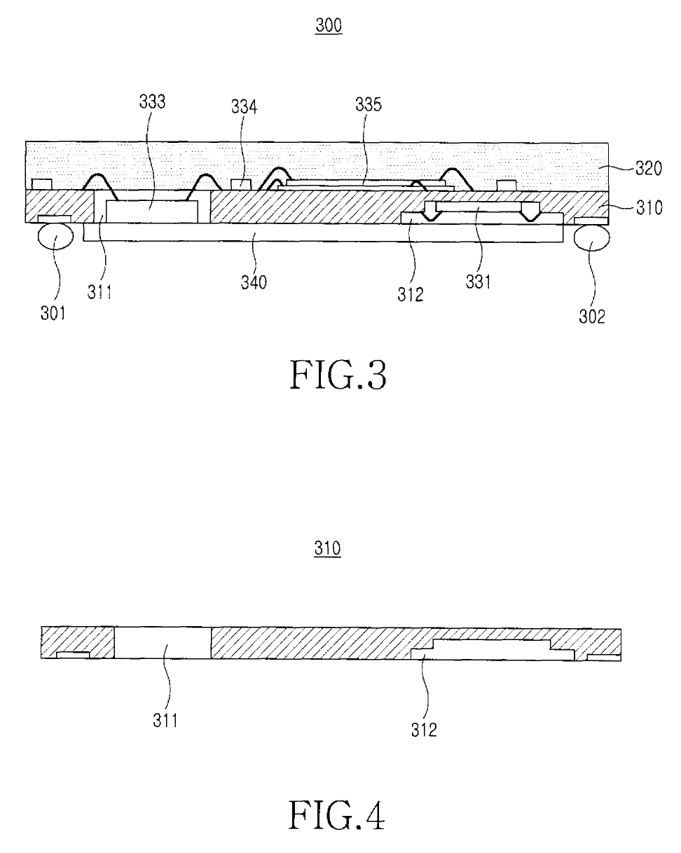

FIG. 3 is a sectional view showing a stacked integration module according to one aspect of the present invention. Referring to FIG. 3, the stacked integration module 300 includes a PCB 310 having first and second surfaces facing each other; a member 340, such as a metallic member 340, having an upper surface on which the second surface of the PCB 310 is disposed; and a molding 320 formed on the first surface of the PCB 310.

The PCB 310 has at least one hole 311 extending through the first and second surfaces and a recess 312 formed on the second surface. A number of components are electrically integrated on the PCB 310. Particularly, a semiconductor chip 333 is disposed in the hole 311. In addition, the semiconductor chip 333 is disposed on the metallic member 340 in such a manner that a surface of the semiconductor chip 333 makes contact with the metallic member 340. A high-frequency device 331 is disposed on the recess 312 so that one side of the high-frequency device 331 is shielded by the metallic member 340. A plurality of passive devices 334 and a semiconductor die 335 are disposed on the first surface of the PCB 310.

The molding 320 is formed so as to cover the first surface of the PCB 310, including the semiconductor chip 311, the high-frequency device 331, and the passive devices 334, all of which are integrated on the PCB 310. The molding 320 is made of any material that solidifies after being applied. For example, the molding 320 may be made of liquid molding resin.

FIGS. 4 to 10 show respective steps for manufacturing the stacked integration module shown in FIG. 3. FIG. 4 shows a PCB 310 having a hole 311 and a recess 312 formed thereon. The hole 311 extends through the first and second surfaces of the PCB 310, and the recess 312 is formed on the second surface of the PCB 310. The PCB 310 has electric wiring patterns formed thereon.

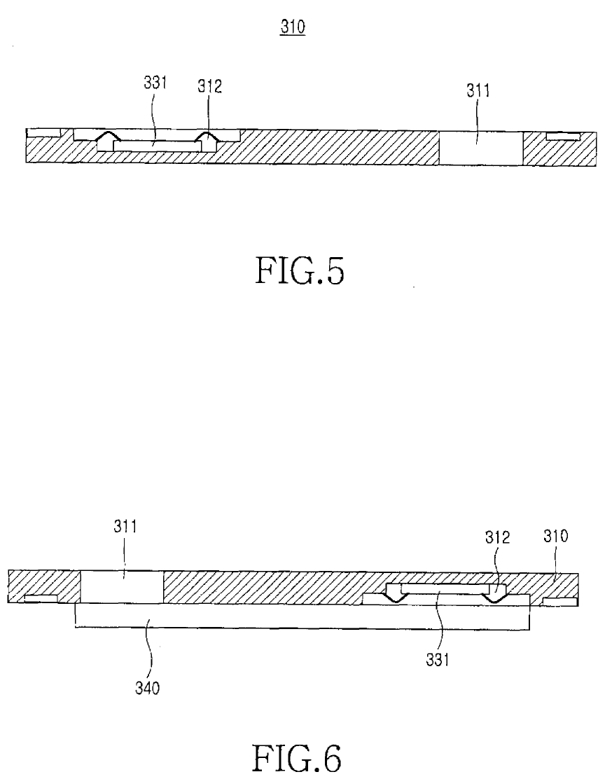

The high-frequency device 331 shown in FIG. 5 is disposed on the recess 312, and may be electrically connected to the PCB 310 by means of, such as, wire bonding. However, the method of electric connection is not limited to the wire bonding, as other method may be used as necessary. For example, electric wiring patterns may be formed on the PCB 310 so as to electrically connect the high-frequency device 331 to the PCB 310.

FIG. 6 shows the PCB 310 having a metallic member 340 attached thereto so as to face the high-frequency device 331 positioned on the recess 312. The metallic member 340 prevents radiation of electromagnetic waves generated by the high-frequency device 331. In addition, the metallic member 340 prevents an end of the hole 311 and the recess 312 from being exposed to external elements.

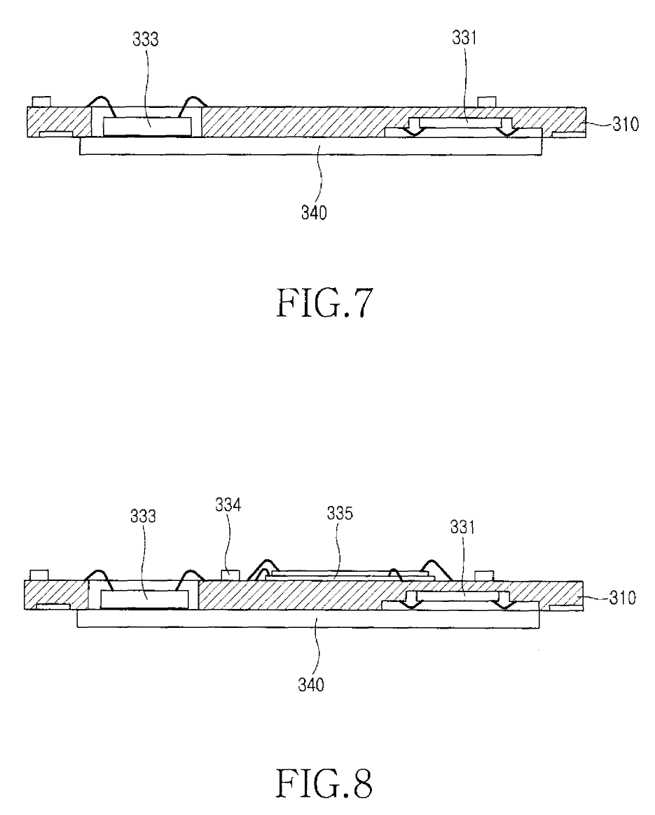

FIG. 7 shows the PCB 310 having a semiconductor chip 333 disposed in the hole 311 in such a manner that a surface of the semiconductor chip 333 makes contact with the metallic member 340. As the semiconductor chip 333 generates more heat than other electronic components contained in the module 300, and as the heat generated by the semiconductor chip 333 is sufficient to raise the temperature of the entire module 300, the temperature of the semiconductor chip 333 needs to be maintained at substantially constant, in order to maintain stable operation characteristics of the module 330.

Stable thermal characteristics of the module 330 are secured by disposing the semiconductor chip 333 such that a surface of the semiconductor chip 333 makes contact with the metallic member 340.

A plurality of passive devices 334, a semiconductor die 335, and other components are integrated on the PCB 310 shown in FIG. 7, and the result is shown in FIG. 8.

A molding 320 is formed on the first surface of the PCB 310 shown in FIG. 8, and the resulting state is shown in FIG. 9. The molding 320 protects the semiconductor chip 333 and the passive devices 334 by preventing them from being exposed to external elements.

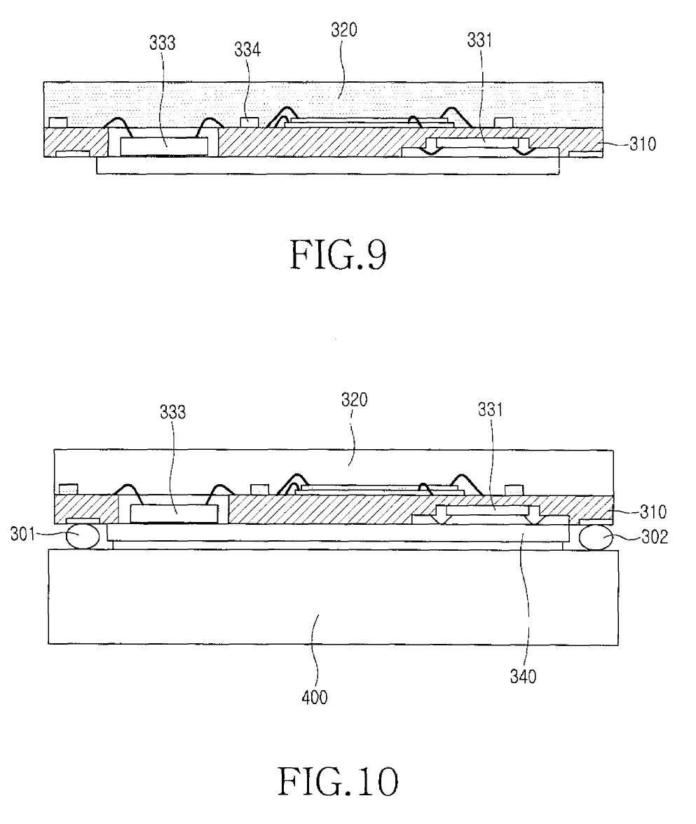

Referring to FIG. 10, the PCB 310 shown in FIGS. 3 to 9 is coupled to an electric substrate 400. Balls 301 and 302 may be positioned between the electric substrate 400 and the PCB 310, electrically connecting them.

As mentioned above, the stacked integration module according to the present invention has several advantages. The present invention induces thermal stability of the semiconductor chip, while preventing radiation of the electromagnetic waves generated by the high-frequency device. The thermal stability and the prevention of the radiation are achieved by attaching a metallic member to the bottom surface of the PCB.

As such, the present invention provides a stacked integration module that is simpler than the conventional modules with respect to the structure of the module and the process of manufacturing the module. The metallic member, which is made of a plate-shaped material having a larger area than conventional heat-radiation means, is advantageous for cooling and electromagnetic wave shielding.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A stacked integration module comprising:
a printed circuit board having first and second surfaces facing each other, at least one hole extending through the first and second surfaces, and a recess formed on the second surface; and
a metallic member having an upper surface, the second surface of the printed circuit board being seated on the upper surface while making contact with the upper surface.

2. The stacked integration module as claimed in claim 1, further comprising:
a semiconductor chip inserted into the hole and positioned so that a surface of the semiconductor chip makes contact with the metallic member;
a high-frequency device seated on the recess so that a side of the high-frequency device is shielded by the metallic member; and
a plurality of passive devices positioned on the first surface of the printed circuit board.

3. The stacked integration module as claimed in claim 2, further comprising a molding configured to cover the first surface of the printed circuit board.

4. The stacked integration module as claimed in claim 3, wherein the molding is made of liquid molding resin.

5. The stacked integration module as claimed in claim 3, wherein the molding comprises a material that solidifies after being applied.

6. The stacked integration module as claimed in claim 1, wherein the metallic member is made of a plate-shaped metallic material.

7. The stacked integration module as claimed in claim 2, wherein the semiconductor chip and the high-frequency device are electrically coupled to the printed circuit board by wire bonding.

8. The stacked integration module as claimed in claim 1, wherein the metallic member is configured to cover the hole.

9. The stacked integration module as claimed in claim 1, wherein the metallic member is configured to cover the recess.

10. The stacked integration module as claimed in claim 1, further comprising an electric substrate.

11. The stacked integration module as claimed in claim 9, further comprising a plurality of balls configured to electrically couple the printed circuit board and the electric substrate.

12. The stacked integration module as claimed in claim 2, wherein the metallic member is configured to prevent radiation of electromagnetic waves generated from the high-frequency device.

13. The stacked integration module as claimed in claim 2, wherein the metallic member is configured to induce thermal stability of the semiconductor chip.

14. The stacked integration module as claimed in claim 2, wherein the metallic member is configured to induce thermal stability of the semiconductor chip and to prevent radiation of electromagnetic waves generated from the high-frequency device.

15. A method for manufacturing a stacked integration module, the method comprising:
forming a printed circuit board having at least one hole and a recess;
integrating a high-frequency device in the recess and making electrical connection;
attaching a metallic member to a surface of the printed circuit board;
inserting a semiconductor chip into the hole and disposing the semiconductor so that a surface of the semiconductor chip makes contact with the metallic member;
integrating a plurality of passive devices on the printed circuit board; and
forming a molding on the printed circuit board.

16. The method as claimed in claim 15, wherein the molding is formed by applying liquid molding resin.

17. The method as claimed in claim 15, further comprising
covering one end of the at least one hole and the recess with the metallic member.

18. The method as claimed in claim 15, further comprising
attaching the metallic member that is configured to prevent radiation of the electromagnetic wave generated from the high-frequency device and that is configured to induce thermal stability of the semiconductor chip.

19. The method as claimed in claim 15, further comprising
electrically coupling an electric substrate to the printed circuit board.

20. The method for operating a stacked integration module, the method comprising:
operating a semiconductor chip that generates heat, that is disposed within at least one hole formed in a printed circuit board, and that is disposed on a surface of a metallic member, the metallic member that is attached to a surface of the printed circuit board;
operating a high-frequency device that generates electromagnetic waves and that is integrated within a recess formed on a surface of the printed circuit board, the recess with an opening covered with the metallic member; and
inducing a thermal stability of the semiconductor chip being operated and simultaneously preventing the radiation of electromagnetic waves generated from the high-frequency device with the metallic member.
